(19) United States
(12) Patent Application Publication
(10) Pub. No.: US 2007/0186415 A1
(43) Pub. Date: Aug. 16, 2007

(54) Anticorrosive bipolar fuel cell board and method for manufacturing the same

(76) Inventors: Hsi-Ming Shu, Taipei (TW); Tsang-Ming Chang, Taipei (TW); Feng-Yi Deng, Taipei (TW); Ko-Chen Shen, Taipei (TW); Wei-Li Huang, Taipei (TW)

Correspondence Address: G. LINK CO., LTD, 3550 Bell Road, MINOOKA, IL, 60447, US

(21) Appl. No.: 11/353,060

(22) Filed: Feb. 14, 2006

(51) Int. Cl. H05K 3/30; B05D 5/12; B32B 37/00

(52) U.S. Cl. 29/832; 427/115; 156/281

(57) ABSTRACT

A method of manufacturing an anticorrosive bipolar fuel cell board is disclosed and comprises the following steps. Step (a) is to provide a first printed circuit substrate with at least a first predetermined region and etch metal on the regions. Step is to provide a second printed circuit substrate with at least a second predetermined region and etch metal on the regions. Step (c) is to respectively cover an anticorrosive conductive material onto the first predetermined regions of the first printed circuit substrate after step (a) such that an anode current collection board is fabricated. Step (d) is to respectively cover an anticorrosive conductive material onto the second predetermined region of the second printed circuit substrate after step (b) such that a cathode current collection board is fabricated. Step (e) is to laminate stacking the anode current collection board, at least a membrane electrode assembly and the cathode current collection board from top to bottom to manufacture a single-piece structure, and thereby an anticorrosive bipolar fuel cell board is fabricated.

### FIELD OF THE INVENTION

The present invention relates to a method of fabricating a fuel cell, and more particularly, to a method of manufacturing an anticorrosive bipolar fuel cell board.

### BACKGROUND OF THE INVENTION

The conventional fuel cell is made from a printed circuit (PCB) substrate, such as a two-sided copper foil substrate, to fabricate a cathode current collection board and an anode current collection board with a printed circuit board (PCB) process etching copper foil on the surfaces of the two-sided copper foil substrate. Then, the surfaces of current collection circuits contacting with membrane electrode assemblies (MEAs) are treated by a protective process or an acid-resisting treatment, to prevent them from being damaged by products of fuel or chemical reactions and to avoid malfunction of the current collection circuits. However, treating the current collection circuits of a conventional fuel cell with a protective process or acid-resisting treatment is not enough since they are substantially made of metal. When a bipolar fuel cell has been used for a long time, the current collection circuit thereof produces precipitates of metal ions that may adhere to the membrane electrode assembly (MEA) layer. As a result, the performance of the bipolar fuel cell becomes poor.

Therefore, an improved method of manufacturing an anticorrosive bipolar fuel cell board is provided to overcome the aforesaid disadvantages.

### SUMMARY OF THE INVENTION

It is a primary object of the invention to provide a method of manufacturing an anticorrosive bipolar fuel cell board, which utilizes to provide an improved method of manufacturing a current collection board.

In accordance with the objects of the invention, a method of manufacturing an anticorrosive bipolar fuel cell board is provided. The method comprises steps of: (a) providing a first printed circuit substrate with at least a first predetermined region, and etching away metal on the first predetermined regions; (b) providing a second printed circuit substrate with at least a second predetermined region, and etching away metal on the second predetermined regions; (c) respectively covering an anticorrosive conductive material on the first predetermined regions of the first printed circuit substrate after step (a) such that an anode current collection board is fabricated; (d) respectively covering an anticorrosive conductive material onto the second predetermined regions of the second printed circuit substrate after step (b) such that a cathode current collection board is fabricated; and (e) laminated stacking the anode current collection board, at least a membrane electrode assembly and the cathode current collection board from top to bottom to manufacture a single-piece structure, and thereby an anticorrosive bipolar fuel cell board is fabricated.

### BRIEF DESCRIPTION OF THE DRAWINGS

The foregoing aspects, as well as many of the attendant advantages and features of this invention will become more apparent by reference to the following detailed description, when taken in conjunction with the accompanying drawings, wherein:

FIG. 1 is a flow chart for manufacturing an anticorrosive bipolar fuel cell board according to the first embodiment of the invention;

FIG. 2A illustrates the structure of a first printed circuit substrate before step 101A is performed;

FIG. 2B illustrates the structure of a first printed circuit substrate after step 101A is performed;

FIG. 3A illustrates the structure of a second printed circuit substrate before step 102A is performed;

FIG. 3B illustrates the structure of a second printed circuit substrate after step 102A is performed;

FIG. 4 illustrates the structure of an anode current collection board fabricated by the first printed circuit substrate of FIG. 2B in step 103A;

FIG. 5 illustrates the structure of a cathode current collection board fabricated by the second printed circuit substrate of FIG. 3B in step 104A;

FIG. 6 illustrates the structure of an anticorrosive bipolar fuel cell board according to the first embodiment of the invention;

FIG. 7 illustrates the structure of an anode current collection board having a layout of electrical circuit according to the first embodiment of the invention;

FIG. 8 illustrates the structure of a cathode current collection board having a layout of electrical circuits according to the first embodiment of the invention;

FIG. 9 is a flow chart for manufacturing an anticorrosive bipolar fuel cell board according to the second embodiment of the invention;

FIG. 10 illustrates the structure of an anode current collection board after performing step 101B to cover an anticorrosive conductive layer onto the first predetermined region of the first substrate;

FIG. 11 illustrates the structure of a cathode current collection board after performing step 102B to cover an anticorrosive conductive layer onto the second predetermined region of the second substrate;

FIG. 12 illustrates the structure of an anticorrosive bipolar fuel cell board according to the second embodiment of the invention;

FIG. 13 illustrates the structure of an anode current collection board having a layout of an electrical circuit according to the second embodiment of the invention;

FIG. 14 illustrates the structure of a cathode current collection board having a layout of electrical circuit according to the second embodiment of the invention;

FIG. 15 is a flow chart for manufacturing an anticorrosive bipolar fuel cell board according to the third embodiment of the invention;

FIG. 16 illustrates the structure of an anode circuitry layer according to the third embodiment of the invention;

FIG. 17 illustrates the structure of a cathode circuitry layer according to the third embodiment of the invention;

FIG. 18 illustrates the structure of an anode current collection board according to the third embodiment of the invention;

FIG. 19 illustrates the structure of a cathode current collection board according to the third embodiment of the invention; and

FIG. 20 illustrates the structure of an anticorrosive bipolar fuel cell board according to the third embodiment of the invention.

### DETAILED DESCRIPTION OF THE INVENTION

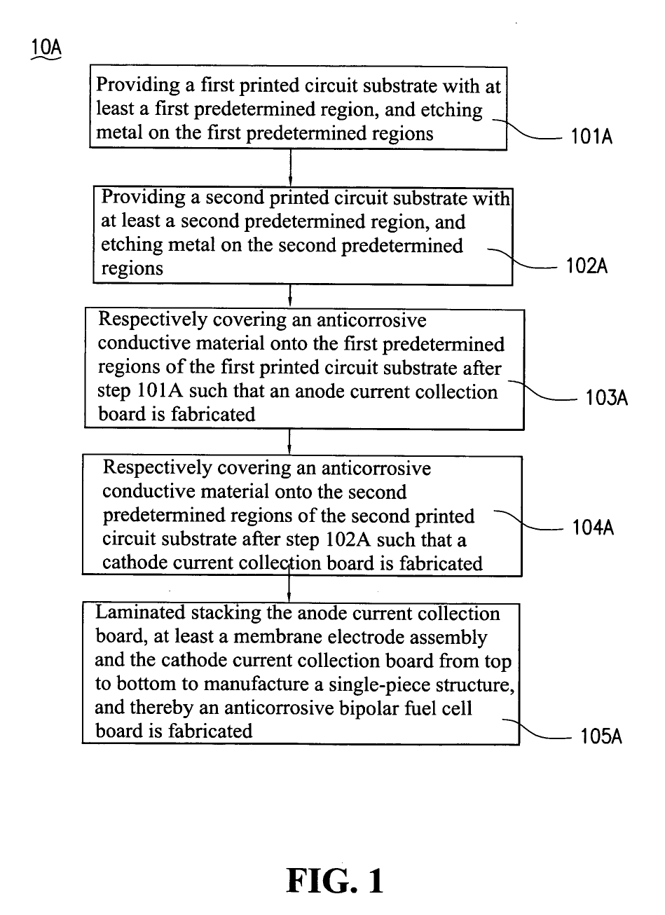

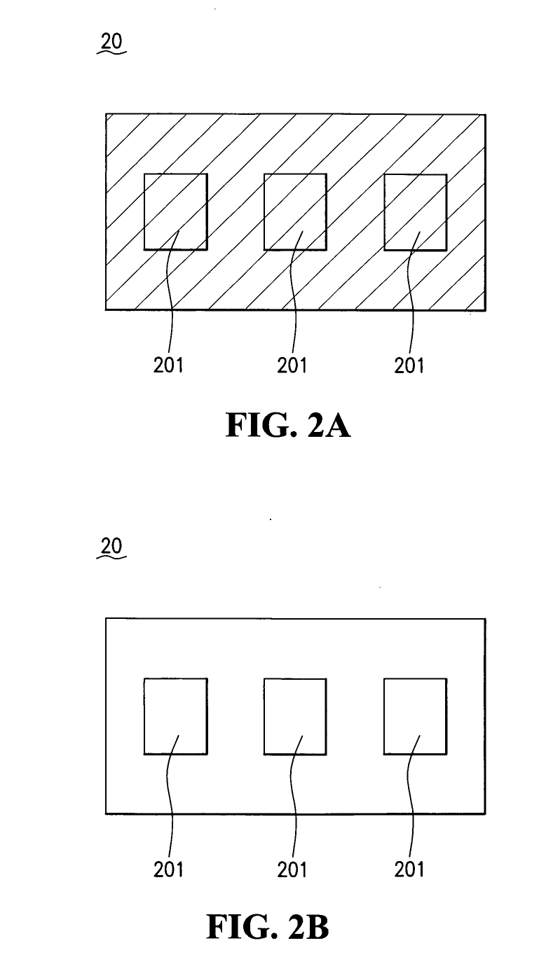

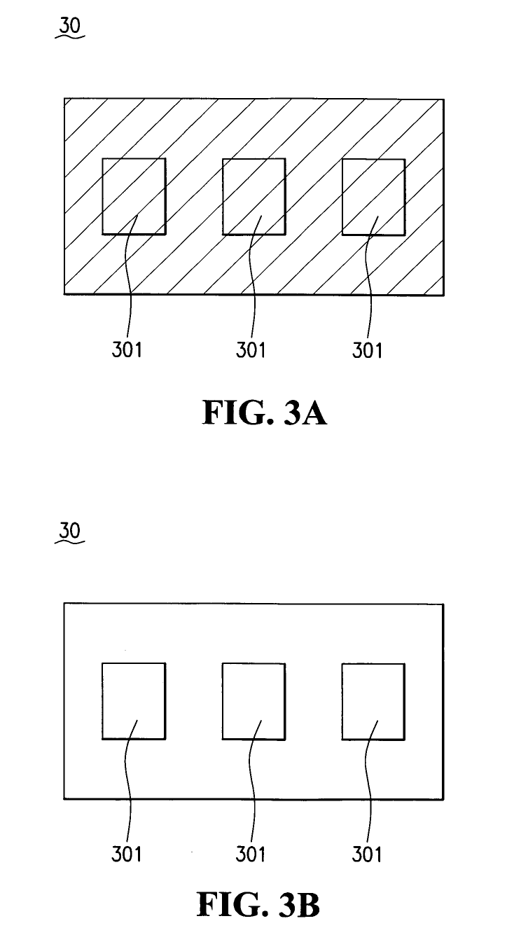

FIG. 1 is a flow chart for manufacturing an anticorrosive bipolar fuel cell board according to the first embodiment of the invention. In the first embodiment, an anode current collection board 21 and a cathode current collection board 31 are manufactured respectively by using a first printed circuit substrate 20 and a second printed circuit substrate 30. The printed circuit substrates 20, 30 may be single-side printed circuit substrates or two-sided printed circuit substrates. A metal layer such as copper foil covers one surface of the single-side printed circuit substrate, and separately covers two surfaces of the two-sided printed circuit substrate. The method 10A to manufacture an anticorrosive bipolar fuel cell board comprises steps 10A, 102A, 103A, 104A, and 105A, which are individually described hereinafter. Step 101A is performed to etch away metal on first predetermined regions 201 of the first printed circuit substrate 20 as marked by oblique of FIG. 2A and FIG. 2B. Referring to FIG. 2A, metal like copper foil on the first predetermined regions 201 of the first printed circuit substrate 20 is not removed. After step 101A is performed, metal on the first predetermined regions 201 of the first printed circuit substrate 20 is removed completely as shown in FIG. 2B. Optionally, metal in other regions is etched as well. Step 102A is performed to etch away metal on the second predetermined regions 301 of the second printed circuit substrate 30 as marked by oblique of FIG. 3A and FIG. 3B. Referring to FIG. 3A, metal like copper foil on the second predetermined regions 301 of the second printed circuit substrate 30 is not removed. After step 102A is performed, metal on the second predetermined region 301 of the second printed circuit substrate 30 is removed completely as shown in FIG. 3B. Optionally, metal in regions except the regions 301 is also etched.

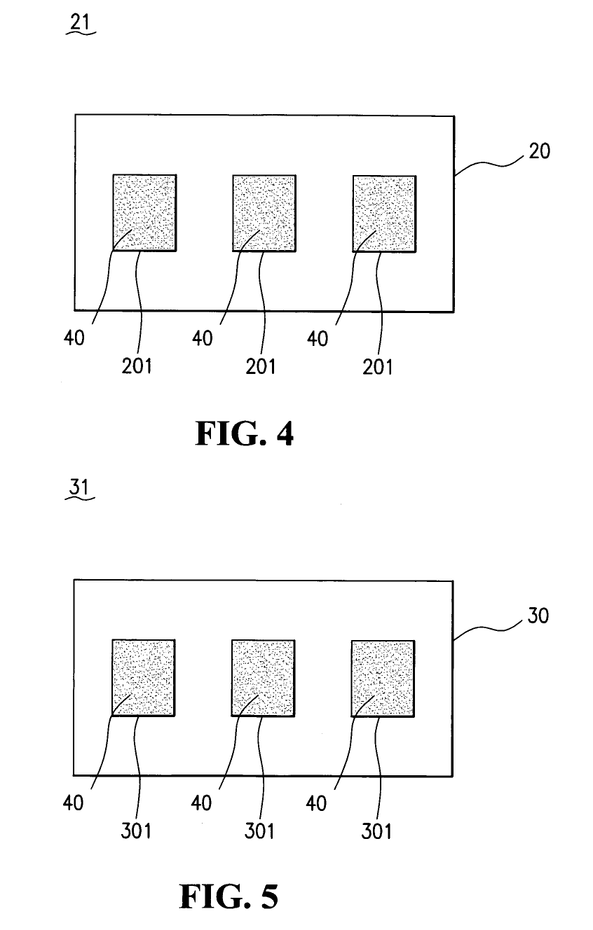

In step 103A, anticorrosive conductive layers 40 are respectively covered on the first predetermined regions 201 of the first printed circuit substrate 20 such that the anode current collection board 21 is fabricated. FIG. 4 shows the structure of the anode current collection board 21 using the first printed circuit substrate 20 of FIG. 2B, wherein the anticorrosive conductive layers 40 are dotted. An anticorrosive conductive material, such as golden (Au), is manufactured on the first predetermined regions 201 of the first printed circuit substrate 20 by, for example, sputtering, depositing, adhering, or carbon inking.

In step 104A, anticorrosive conductive layers 40 are manufactured on the second predetermined regions 301 of the second printed circuit substrate 30 after step 102A, and then the cathode current collection board 31 is fabricated. FIG. 5 shows the structure of the cathode current collection board 31 using the second printed circuit substrate 30 of FIG. 3B, wherein the anticorrosive conductive layers 40 are dotted. An anticorrosive conductive material, such as golden (Au), is covered on the second predetermined regions 301 of the second printed circuit substrate 30 by, for example, sputtering, depositing, adhering, or carbon inking.

In step 105A, the anode current collection board 21, at least a membrane electrode assembly (MEA) 50 and the cathode current collection board 31 are laminated and stacked from top to bottom, so as to manufacture an anticorrosive bipolar fuel cell board 60.

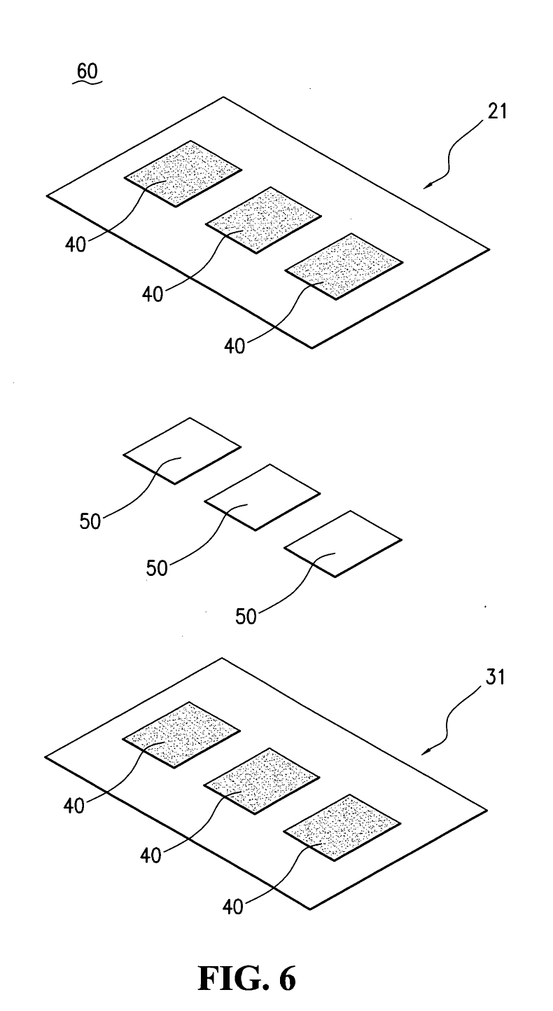

FIG. 6 illustrates the structure of an anticorrosive bipolar fuel cell board fabricated by the method of the first embodiment. As shown in FIG. 6, the anode current collection board 21, at least a MEA 50 and the cathode current collection board 31 are connected firmly by laminated stacking the same from top to bottom, and thereby a sealed single-piece structure of anticorrosive bipolar fuel cell board 60 is fabricated.

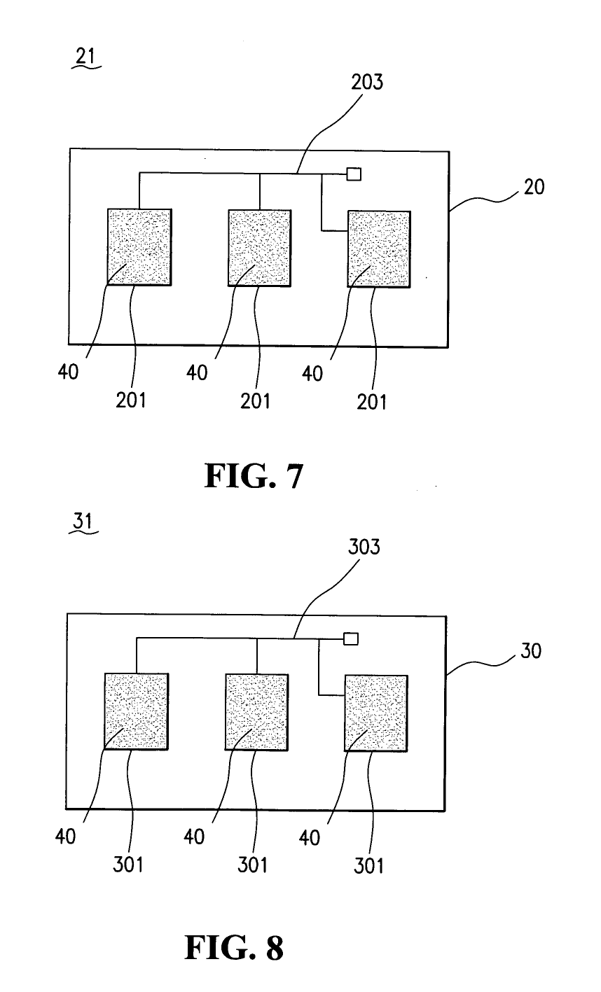

Furthermore, step 101A further includes etching metal to form a layout 203 of electrical circuit on the first printed circuit substrate 20. Referring to FIG. 7, the layout 203 of the electrical circuit is manufactured by performing an etch process of PCB processes to etch metal on the regions other than the first predetermined region 201 of the anode current collection board 21.

Step 102A further includes etching metal to form a layout 303 of electrical circuit on the second printed circuit substrate 30. Referring to FIG. 8, the layout 303 of the electrical circuit is manufactured by performing an etching process of PCB processes to etch metal on the regions other than the second predetermined region 301 of the cathode current collection board 31.

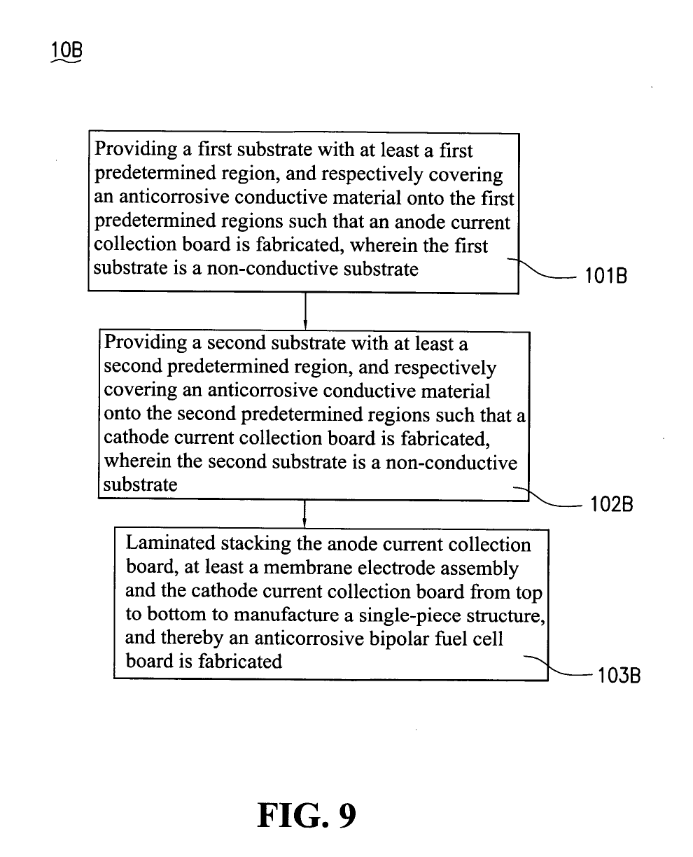

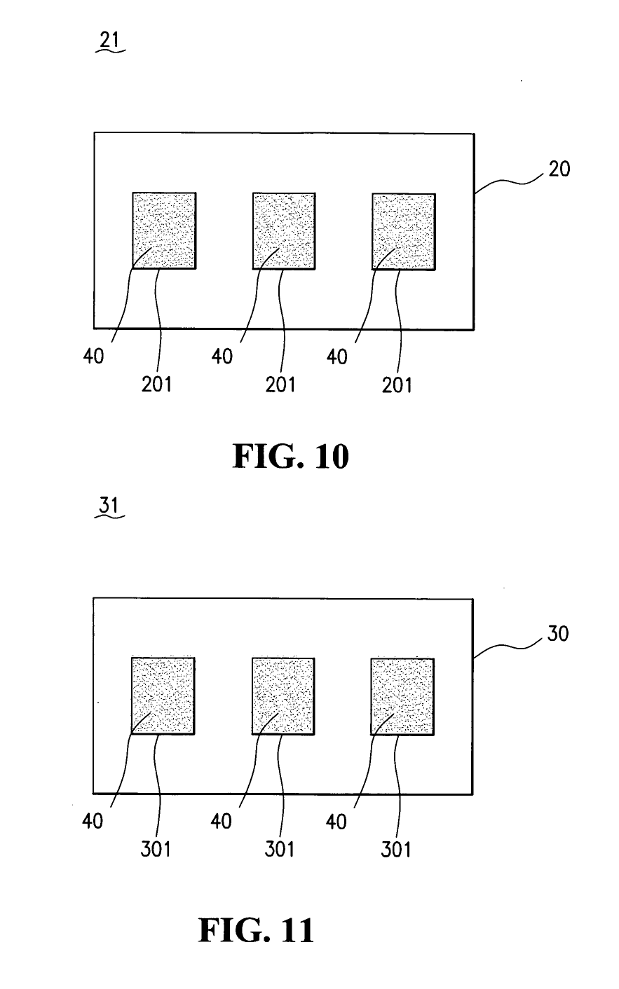

FIG. 9 is a flow chart for manufacturing an anticorrosive bipolar fuel cell board according to the second embodiment of the invention. In the embodiment, a first substrate 20 and a second substrate 30 are used to manufacture an anode current collection board 21 and a cathode current collection board 31, respectively. The substrates 20, 30 may be made of insulating material, such as epoxy glass fiber substrates, ceramic substrates or polymer plastic substrates. The method 10B to manufacture an anticorrosive bipolar fuel cell board comprises steps 101B, 102B and 103B, which are individually described hereinafter. Step 101B is performed to cover anticorrosive conductive layers 40 on the first predetermined regions 201 of the first substrate 20, respectively, so as to fabricate the anode current collection board 21. The anticorrosive conductive layers 40 are marked with dotted in FIG. 10. After performing step 101B, the anode current collection board 21 is manufactured by utilizing an anticorrosive conductive material, such as Au, to cover the first predetermined regions 201 of the first substrate 20.

Step 102B is performed to cover anticorrosive conductive layers 40 on the second predetermined regions 301 of the second substrate 30, respectively, so as to fabricate the cathode current collection board 31. The anticorrosive conductive layers 40 are dotted in FIG. 11.

In the second embodiment, an anticorrosive conductive material, such as golden (Au), is covered on the predetermined regions 201, 301 by sputtering, depositing, adhering, or carbon inking.

In step 103B, the anode current collection board 21, at least a MEA 50 and the cathode current collection board 31 are laminated and stacked from top to bottom, so as to manufacture an anticorrosive bipolar fuel cell board 60.

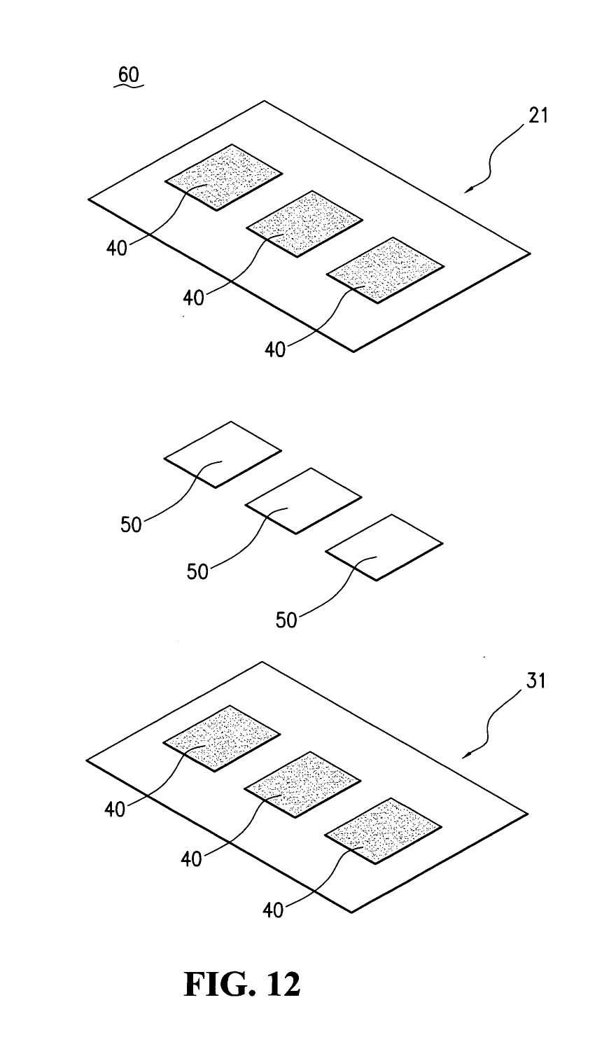

FIG. 12 illustrates the structure of an anticorrosive bipolar fuel cell board fabricated by the method of the second embodiment. As shown in FIG. 12, the anode current collection board 21, at least a MEA 50 and the cathode current collection board 31 are connected firmly by laminated stacking the same from top to bottom such that a sealed single-piece structure of anticorrosive bipolar fuel cell board 60 is fabricated.

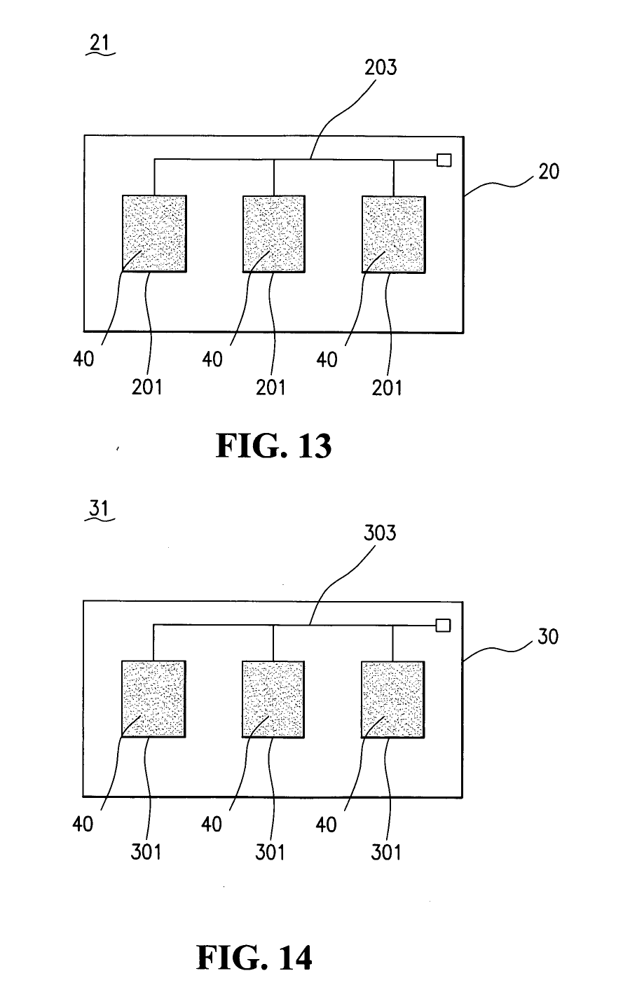

Step 101B further includes manufacturing a layer of anticorrosive conductive material on the regions except the first predetermined regions 201 of the first substrate 20, so as to form a layout 203 of electrical circuit. Referring to FIG. 13, the layout 203 of electrical circuit is manufactured by covering an anticorrosive conductive material onto the regions other than the first predetermined regions 201.

Step 102B further includes manufacturing a layer of anticorrosive conductive material on the regions except the second predetermined regions 301 of the second substrate 30, so as to form a layout 303 of electrical circuit. Referring to FIG. 14, the layout 303 of electrical circuit is manufactured by covering an anticorrosive conductive material onto the regions other than the second predetermined regions 301.

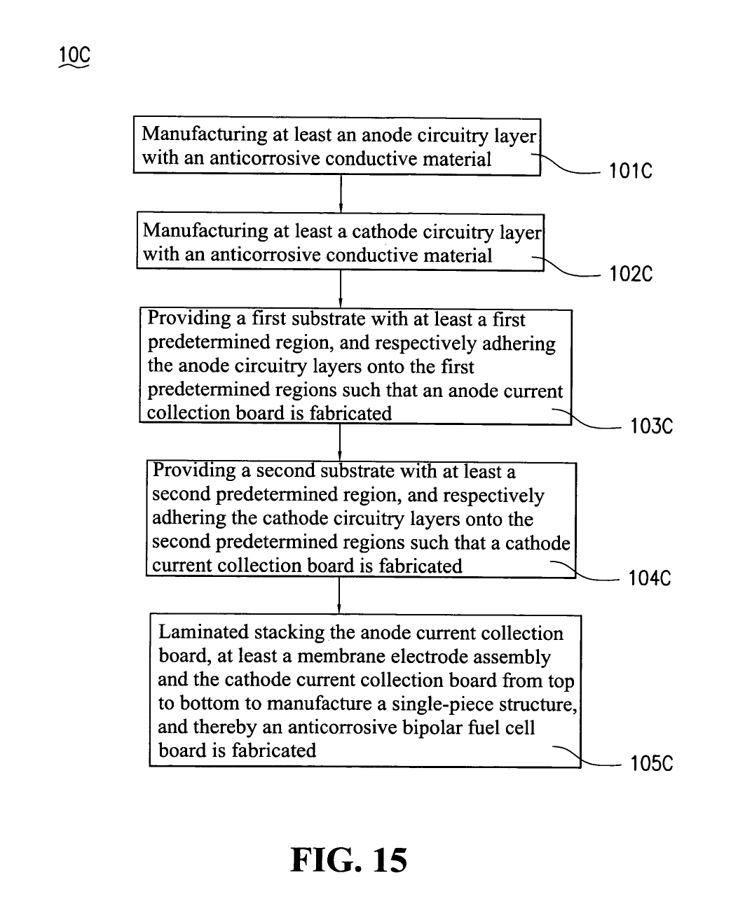

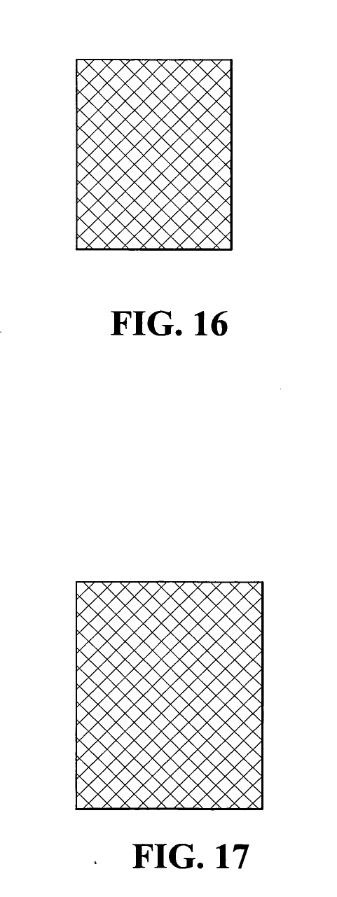

FIG. 15 is a flow chart for manufacturing an anticorrosive bipolar fuel cell board according to the third embodiment of the invention. In the embodiment, a first substrate 20, a second substrate 30, a fabricated anode circuitry layer, and a fabricated cathode circuitry layer are used to manufacture an anode current collection board 21 and a cathode current collection board 31, respectively. The substrates 20, 30 may be made of insulating material, such as epoxy glass fiber substrates, ceramic substrates or polymer plastic substrates. The method 10C to manufacture an anticorrosive bipolar fuel cell board comprises steps 101C, 102C, 103C, 104C, and 105C, which are individually described hereinafter. Step 101C is performed to fabricate an anode circuitry layer having anticorrosive conductive material, and step 102C is performed to fabricate a cathode circuitry layer having anticorrosive conductive material. Steps 101C and 102C are performed by, for instance, stamping an Au lamina to manufacture a structure of a porous network or a frame structure. Accordingly, the fabricated anode circuitry layer and the fabricated cathode circuitry layer are manufactured. References are made to FIG. 16 showing an exemplary structure of the anode circuitry layer and FIG. 17 showing an exemplary structure of the cathode circuitry layer.

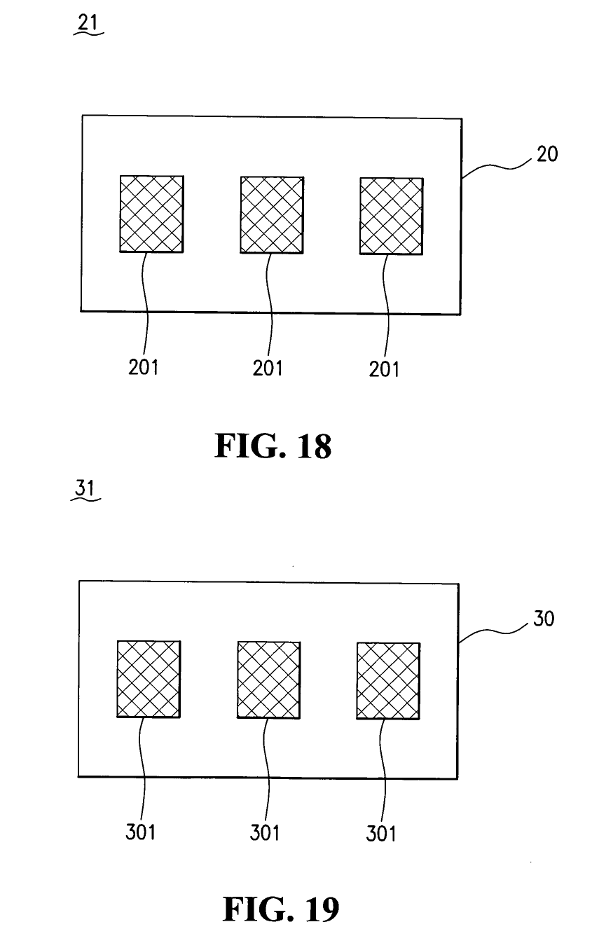

Step 103C is performed to fabricate the anode current collection board 20 by respectively stamping the anode circuitry layers onto the first predetermined regions 201 of the first substrate 20 with reference to FIG. 18. Step 104C is performed to fabricate the cathode current collection board 30 by respectively stamping the cathode circuitry layers onto the second predetermined regions 301 of the second substrate 30 with reference to FIG. 19.

In step 105C, the anode current collection board 21, at least a MEA 50 and the cathode current collection board 31 are laminated and stacked from top to bottom, so as to manufacture an anticorrosive bipolar fuel cell board 60.

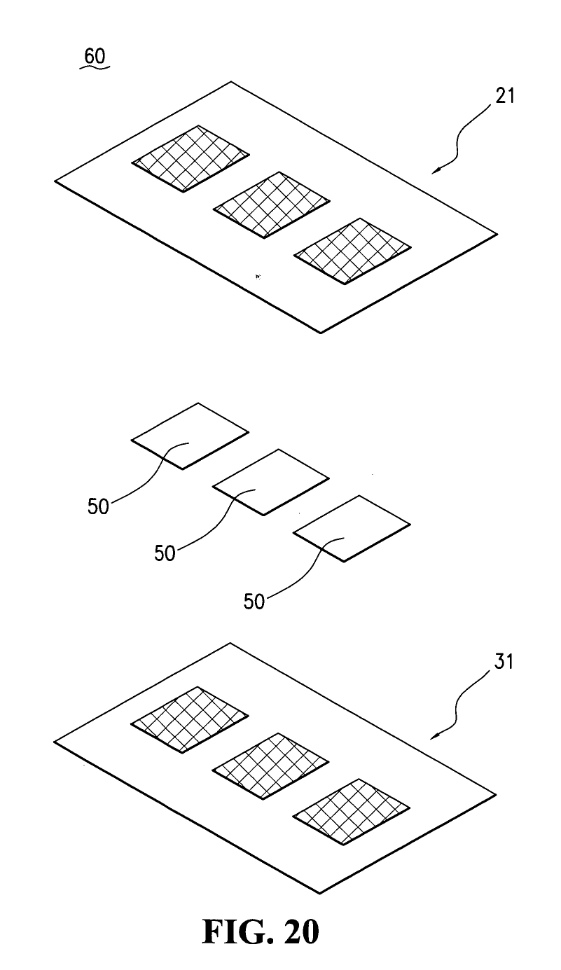

FIG. 20 illustrates the structure of an anticorrosive bipolar fuel cell board fabricated by the method of the third embodiment. As shown in FIG. 20, the anode current collection board 21, at least a MEA 50 and the cathode current collection board 31 are connected firmly by laminated stacking the same from top to bottom such that a sealed single-piece structure of anticorrosive bipolar fuel cell board 60 is fabricated.

The first predetermined regions 201 and the second predetermined regions 301 described in the above embodiments may be drilled, in order to flow anode fuels and cathode fuels into the MEAs. Accordingly, porous structures are manufactured within the first predetermined regions 201 and the second predetermined regions 301 for the drift of anode fuels and cathode fuels and for the drain of products generated during the electrochemical reaction of MEAs 50. Alternately, hollow structures like rectangular hollow structures may be manufactured within the first predetermined regions 201 and the second predetermined regions 301.

While the invention has been particularly shown and described with reference to the preferred embodiments thereof, these are, of course, merely examples to help clarify the invention and are not intended to limit the invention. It will be understood by those skilled in the art that various changes, modifications, and alterations in manufacture and detail may be made therein without departing from the spirit and scope of the invention, as set forth in the following claims.

What is claimed is:

1. A method of manufacturing an anticorrosive bipolar fuel cell board, the method comprising steps of:
(A). providing a first printed circuit substrate with at least a first predetermined region, and etching metal on the first predetermined regions;
(b). providing a second printed circuit substrate with at least a second predetermined region, and etching metal on the second predetermined regions;
(c). respectively covering an anticorrosive conductive material onto the first predetermined regions of the first printed circuit substrate after step (a) such that an anode current collection board is fabricated;
(d). respectively covering an anticorrosive conductive material onto the second predetermined regions of the second printed circuit substrate after step (b) such that a cathode current collection board is fabricated; and
(e). laminated stacking the anode current collection board, at least a membrane electrode assembly and the cathode current collection board from top to bottom to manufacture a single-piece structure, and thereby an anticorrosive bipolar fuel cell board is fabricated.

2. The method of claim 1, wherein the first printed circuit substrate is a single-side printed circuit substrate or a two-sided printed circuit substrate.

3. The method of claim 1, wherein the second printed circuit substrate is a single-side printed circuit substrate or a two-sided printed circuit substrate.

4. The method of claim 1, wherein step (c) and step (d) are performed by selecting one means of sputtering, depositing, adhering, and carbon inking.

5. The method of claim 1, wherein step (a) further comprises etching the metal on the first printed circuit substrate to form a layout of an electrical circuit.

6. The method of claim 1, wherein step (b) further comprises etching the metal on the second printed circuit substrate to form a layout of an electrical circuit.

7. A method of manufacturing an anticorrosive bipolar fuel cell board, the method comprising steps of:
(a). providing a first substrate with at least a first predetermined region, and respectively covering an anticorrosive conductive material onto the first predetermined regions such that an anode current collection board is fabricated, wherein the first substrate is a non-conductive substrate;
(b). providing a second substrate with at least a second predetermined region, and respectively covering an anticorrosive conductive material onto the second predetermined regions such that a cathode current collection board is fabricated, wherein the second substrate is a non-conductive substrate; and
(c). laminated stacking the anode current collection board, at least a membrane electrode assembly and the cathode current collection board from top to bottom to manufacture a single-piece structure, and thereby an anticorrosive bipolar fuel cell board is fabricated.

8. The method of claim 7, wherein the first substrate is an epoxy glass fiber substrate, a ceramic substrate or a polymer plastic substrate.

9. The method of claim 7, wherein the second substrate is an epoxy glass fiber substrate, a ceramic substrate or a polymer plastic substrate.

10. The method of claim 7, wherein step (a) and step (b), are performed by selecting one means of sputtering, depositing, adhering, and carbon inking.

11. The method of claim 7, wherein step (a) further comprises covering a layout structure with anticorrosive conductive material onto the first substrate to form a layout of electrical circuit.

12. The method of claim 7, wherein step (b) further comprises covering a layout structure with anticorrosive conductive material onto the second substrate to form a layout of electrical circuit.

13. The method of claim 11, wherein covering the layout structure is performed by selecting one means of sputtering, depositing, adhering, and carbon inking.

14. The method of claim 12, wherein covering the layout structure is performed by selecting one means of sputtering, depositing, adhering, and carbon inking.

15. A method of manufacturing an anticorrosive bipolar fuel cell board, the method comprising steps of:
(A). manufacturing at least an anode circuitry layer with an anticorrosive conductive material;
(b). manufacturing at least a cathode circuitry layer with an anticorrosive conductive material;
(c). providing a first substrate with at least a first predetermined region, and respectively adhering the anode circuitry layers onto the first predetermined regions such that an anode current collection board is fabricated;
(d). providing a second substrate with at least a second predetermined region, and respectively adhering the cathode circuitry layers onto the second predetermined regions such that a cathode current collection board is fabricated; and
(e). laminated stacking the anode current collection board, at least a membrane electrode assembly and the cathode current collection board from top to bottom to manufacture a single-piece structure, and thereby an anticorrosive bipolar fuel cell board is fabricated.

16. The method of claim 15, wherein the first predetermined region is a hollow region.

17. The method of claim 15, wherein the second predetermined region is a hollow region.

18. The method of claim 15, wherein a structure of the layer of the anode circuit is selected from a group consisting of a porous network structure or a frame structure.

19. The method of claim 15, wherein a structure of the cathode circuitry layer is selected from a group consisting of a porous network structure or a frame structure.
